(19) United States
(12) Patent Application Publication
(10) Pub. No.: US 2026/0145931 A1
(43) Pub. Date: May 28, 2026

(54) INERTIA MEASUREMENT UNIT AND METHOD FOR FORMING THE SAME

(71) Applicant: AAC Technologies Pte. Ltd., Singapore (SG)

(72) Inventors: Qiuyu Tan, Singapore (SG); Houming Chong, Johor (MY); Zaixiang Pua, Singapore (SG); Zhan Zhan, Shenzhen (CN); Kahkeen Lai, Singapore (SG)

(21) Appl. No.: 18/961,311

(22) Filed: Nov. 26, 2024

(51) Int. Cl. B81B 7/00; B81C 1/00

(52) U.S. Cl. CPC B81B 7/0061; B81C 1/00309; B81B 2201/0228; B81B 2203/0315; B81B 2203/0338; B81C 2201/013; B81C 2201/0159; B81C 2201/0198; B81C 2203/033

(57) ABSTRACT

Provided are an inertia measurement unit and a method therefor. The inertia measurement unit includes: a first base; a dielectric layer including a notch; a first electric-conductive layer including first openings; a second electric-conductive layer, second openings being formed in the second electric-conductive layer; a second base covering the second electric-conductive layer, a closed space being formed between the second base and the first base, the closed space including a plurality of cavities spaced from one another and having different cavity pressures; a gas-exhaust channel connected to one of the plurality of cavities and configured to connect the one of the plurality of cavities with an outer environment; and a closure portion configured to close the gas-exhaust channel. Cavities having different cavity pressures are formed at a single wafer, and it facilitates formation of an inertia measurement unit that assembles two or more inertial sensors together.

### TECHNICAL FIELD

The present disclosure relates to the technical field of micro-electromechanical systems, in particular to an inertia measurement unit and a method for forming the same.

### BACKGROUND

Use of two or more inertia sensors of different cavity pressures together on a single component module is typically known as the inertia measurement unit (IMU). The IMU is popular as it enables the measurement of both acceleration and angular velocity in a single component.

Traditional IMU are constructed with individual inertial sensors die chip with different pressure that are fabricated separately on different wafers, and then being placed together as a single component.

Such a method cost double the fabrication material and fabrication cycle time to create a single IMU with two sensors of different cavity pressures. The cost and resources further multiply when more sensors with different cavity pressures need to be assembled in a single IMU.

### SUMMARY

The present disclosure aims to providing an inertial sensor and a method for forming the same, to solve the technical problems in the prior art. By the present disclosure, two or more inertial sensors having different cavity pressures can be formed at a single wafer.

In an aspect, an embodiment of the present disclosure provides an inertia measurement unit, including: a first base; a dielectric layer stacked on the first base and including a notch; a first electric-conductive layer stacked on the dielectric layer, first openings being formed in the first electric-conductive layer; a second electric-conductive layer supported on the first electric-conductive layer by means of a support portion, second openings being formed in the second electric-conductive layer; a second base, the second base covering the second electric-conductive layer by means of a bonding structure, a closed space being formed between the second base and the first base, the closed space including a plurality of cavities spaced from one another, and the plurality of cavities having different cavity pressures; a gas-exhaust channel connected to one of the plurality of cavities and configured to connect the one of the plurality of cavities with an outer environment; and a closure portion configured to close the gas-exhaust channel.

As an improvement, the gas-exhaust channel includes a first channel section and a second channel section, an end of the first channel section is connected to the outer environment, another end of the first channel section is connected to an end of the second channel section, and another end of the second channel section is connected to the cavity connected to the gas-exhaust channel.

As an improvement, the second channel section includes a plurality of gas-exhaust sub-channels successively connected to one another.

As an improvement, the first channel section and the second channel section perpendicularly intersect with each other.

As an improvement, the number of the plurality of cavities is set to be n, where n≥2; and the number of cavities connected to the gas-exhaust channel is set to be (n−1) or n.

As an improvement, the sealed space includes a first cavity and a second cavity spaced from each other, a cavity pressure in the first cavity is greater than a cavity pressure in the second cavity, the gas-exhaust channel is formed in the second base and the bonding structure, an end of the gas-exhaust channel forms a first aperture at an outer wall of the second base, another end of the gas-exhaust channel forms a second aperture at an inner wall of the bonding structure, and the gas-exhaust channel is connected to the first cavity via the second aperture.

As an improvement, the first aperture is formed at a top surface of the second base, and the closure portion covers the top surface of the second base to close the first aperture.

As an improvement, the bonding structure includes a first bonding layer and a second bonding layer connected by bonding, the first bonding layer is stacked at a top of the second electric-conductive layer, and the second bonding layer is stacked at a bottom of the second base.

As an improvement, a plurality of connection blocks are formed by protruding from a bottom surface of the second base, the plurality of connection blocks are connected to the bonding structure, and a groove is formed between adjacent connection blocks of the plurality of connection blocks.

In another aspect, an embodiment of the present disclosure provides a method for forming an inertia measurement unit, the inertia measurement unit including: a first base; a dielectric layer stacked on the first base and including a notch; a first electric-conductive layer stacked on the dielectric layer, first openings being formed in the first electric-conductive layer; a second electric-conductive layer supported on the first electric-conductive layer by means of a support portion, second openings being formed in the second electric-conductive layer; a second base, the second base covering the second electric-conductive layer by means of a bonding structure, a closed space being formed between the second base and the first base, the closed space including a plurality of cavities spaced from one another, and the plurality of cavities having different cavity pressures; a gas-exhaust channel connected to one of the plurality of cavities and configured to connect the one of the plurality of cavities with an outer environment; and a closure portion configured to close the gas-exhaust channel. The method for forming the inertia measurement unit includes: forming the first base; forming the dielectric layer and the first electric-conductive layer on the first base, the dielectric layer including the notch; and forming the first openings in the first electric-conductive layer; forming the second electric-conductive layer on the first electric-conductive layer, and forming a first bonding layer on the second electric-conductive layer; forming the second openings in the second electric-conductive layer, and forming the support portion at the second electric-conductive layer; forming the second base; forming a second bonding layer on the second base; forming a groove at the second base; bonding the first bonding layer and the second bonding layer together at a high temperature to form the bonding structure, and forming the closed space between the second base and the first base, the closed space including the plurality of cavities spaced from one another; forming the gas-exhaust channel in the second base and the bonding structure to release air in at least one of the plurality of cavities; forming the closure portion by depositing on the second base, to close the gas-exhaust channel; and forming the inertia measurement unit.

Compared with the related art, in the present disclosure, at least one gas-exhaust channel is connected to at least one cavity, so that air can be extracted from the gas-exhaust channel and escapes from the cavity, and then the gas-exhaust channel is closed using a closure portion. In the present disclosure, a plurality of cavities having different cavity pressures are formed at a single wafer. This facilitates formation of an inertia measurement unit that assembles two or more inertial sensors together, thereby allowing the inertia measurement units to be differentiated according to different functions and performance specifications required. Since the inertia sensors have similar materials and forming processes, the present disclosure can reduce the forming cycle time, material and cost per unit of the inertia measurement unit.

### BRIEF DESCRIPTION OF DRAWINGS

FIG. 1 is a schematic cross-sectional view of an inertial sensor according to an embodiment of the present disclosure;

FIGS. 2A-2C are schematic cross-sectional views along A-A shown in FIG. 1 (gas-exhaust channels of various structures); and

FIGS. 3A-3J are flow charts of a method for forming an inertial sensor according to an embodiment of the present disclosure.

### REFERENCE SIGNS

1. first base;
2. dielectric layer;
3. first electric-conductive layer;
4. first opening;
5. second electric-conductive layer;
6. second opening;
7. support portion;
   71. support block;
8. bonding structure;
   81. first bonding layer;
   82. second bonding layer;
9. second base;
10. connection block;
11. groove;
12. gas-exhaust channel;
   121. first channel section;
   122. second channel section;
   123. gas-exhaust sub-channel;
13. closure portion;
14. cavity;
   141. first cavity;
   142. second cavity;
15. notch.

### DESCRIPTION OF EMBODIMENTS

The embodiments described below with reference to the drawings are exemplary and are only used to illustrate the present disclosure and cannot be construed as limiting the present disclosure.

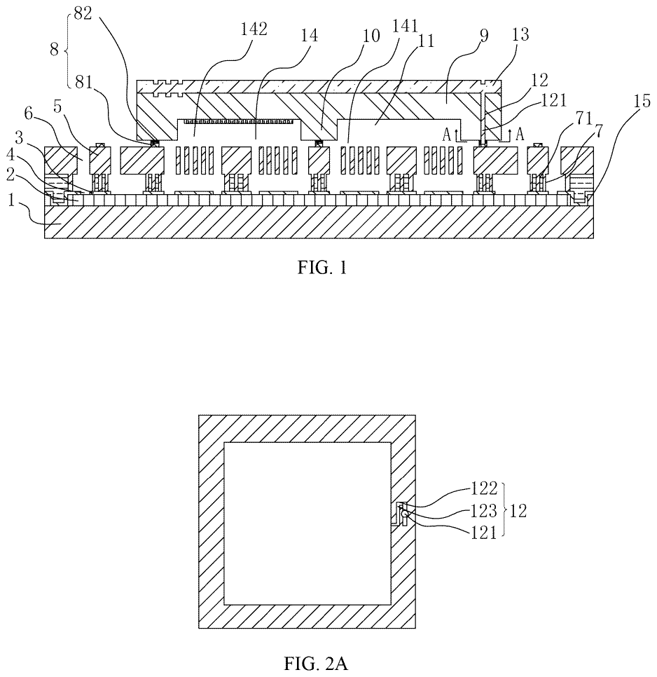

As shown in FIG. 1, an embodiment of the present disclosure provides an inertial sensor, including a first base 1, a dielectric layer 2, a first electric-conductive layer 3, a second electric-conductive layer 5 and a second base 9 that are arranged in a direction from bottom to top.

The first base 1 is a semiconductor substrate, such as a silicon substrate. In a possible implementation, the first base 1 is formed as a circular shape. Those skilled in the art should know that the first base 1 can also be formed as other shape, such as a square, etc., which are not limited herein.

The dielectric layer 2 is stacked on the first base 1. A shape of the dielectric layer 2 is adapted to the shape of the first base 1. The dielectric layer 2 is used to support the first electric-conductive layer 3, and make the first electric-conductive layer 3 electrically insulated from the first base 1. The dielectric layer 2 includes a notch 15. In a feasible implementation, the dielectric layer 2 is made of silicon dioxide.

The first electric-conductive layer 3 is stacked on the dielectric layer 2. A shape of the first electric-conductive layer 3 is adapted to the shape of the dielectric layer 2. First openings 4 are formed in the first electric-conductive layer 3. The first electric-conductive layer 3 is made of an electric-conductive material, such as polysilicon.

The second electric-conductive layer 5 is supported on the first electric-conductive layer 3 by means of the support portion 7. The support portion 7 is used to support the second electric-conductive layer 5, so that a gap is formed between the second electric-conductive layer 5 and the first electric-conductive layer 3 to provide a space for deformation of the second electric-conductive layer 5. Second openings 6 are formed in the second electric-conductive layer 5. The second electric-conductive layer 5 is made of an electric-conductive material, such as polysilicon.

The second base 9 covers the second electric-conductive layer 5 by means of a bonding structure 8. The bonding structure 8 includes a first bonding layer 81 and a second bonding layer 82 connected to each other by bonding. The first bonding layer 81 is stacked at a top of the first electric-conductive layer 3, and the second bonding layer 82 is stacked at a bottom of the second electric-conductive layer 5. Each of the first bonding layer 81 and the second bonding layer 82 is made of metal, to form metal hot-press bonding.

The second base 9 is a semiconductor substrate, such as a silicon substrate. In a feasible implementation, the second base 9 is formed as a circular shape. Those skilled in the art should know that the second base 9 can also be formed as other shape, such as square, etc., which will not be limited herein. A closed space is formed between the second base 9 and the first base 1, thereby preventing an internal structure of the inertial sensor from being disturbed by an external environment, and thus facilitating control of an air pressure in the cavity and improving the working stability.

The closed space is provided with cavities 14 spaced from one another. The cavities 14 have different cavity pressures. At least two cavities 14 are provided, and a specific number of the cavities 14 and the cavity pressures of the respective cavities 14 can be determined according to actual needs and are not limited herein. In an embodiment, a gas-exhaust channel 12 is provided. A position of the gas-exhaust channel 12 can be arranged at any wall of the cavity 14. An end of the gas-exhaust channel 12 is connected to an interior of the cavity 14, and another end of the gas-exhaust channel 12 is connected to an outer environment. In an embodiment, the gas-exhaust channel 12 is connected to each of at least one cavity 14. In an example, the number of the cavities 14 is set to n (n≥2), and the number of the cavities 14 connected to the respective gas-exhaust channel(s) 12 is set to (n−1) or n.

In an example, two cavities 14 are provided, and the gas-exhaust channel 12 is provided in only one of the two cavities 14. The gas-exhaust channel 12 is used to exhaust the one cavity 14 connected thereto, and air is exhausted from the gas-exhaust channel 12 and escape from the cavity 14. The other one of the two cavities 14 maintains at an initial cavity pressure. In this way, the cavities 14 in a single wafer can have different cavity pressures. In another example, the gas-exhaust channel 12 can be arranged in each of the two cavities 14, so that the cavity pressures in the two cavities 14 are respectively different from an initial cavity pressure, and are also different from each other.

One cavity 14 may be connected to one gas-exhaust channel 12 or at least two gas-exhaust channels 12, which will not be limited herein. In an example, one cavity 14 is connected to at least two gas-exhaust channels 12, so that the air in the one cavity 14 can be exhausted faster, however, in this case, it may lead to a more complicated structure and poor sealing stability. In another example, each of at least one cavity 14 is connected to only one gas-exhaust channel 12.

After the cavity pressure in each cavity 14 reaches a preset value, the respective gas-exhaust channel 12 is closed by a closure portion 13, so that each cavity 14 is restored to be a closed cavity, thereby improving the working stability. The closure portion 13 is made of a dielectric or electric-conductive material, which will not be limited herein.

In an embodiment, in order to prevent a deposition material for sealing being deposited into the gas-exhaust channel 12 when the closure portion 13 closes the gas-exhaust channel 12, the gas-exhaust channel 12 includes a first channel section 121 and a second channel section 122. An end of the first channel section 121 is connected to an outer environment, and another end of the first channel section 121 is connected to an end of the second channel section 122, while another end of the second channel section 122 is connected to the cavity 14. When the closure portion 13 closes the gas-exhaust channel 12, the deposition material of the closure portion 13 flows in the first channel section 121. Since the extending direction of the first channel section 121 is not parallel to the extending direction of the second channel section 122, flowing of the deposition material of the closure portion 13 will be hindered at a turning corner, to prevent the deposition material of the closure portion 13 from flowing into the cavity 14.

Further, the second channel section 122 includes a plurality of gas-exhaust sub-channels 123 sequentially connected to one another. The plurality of gas-exhaust sub-channels 123 are located in a same plane. In this case, a plurality of turning corners can be formed at adjacent gas-exhaust sub-channels 123, thereby more effectively hindering flowing of the deposition material in the closure portion 13, thereby preventing the deposition material from being deposited into the cavity 14 to affect the performance of the device.

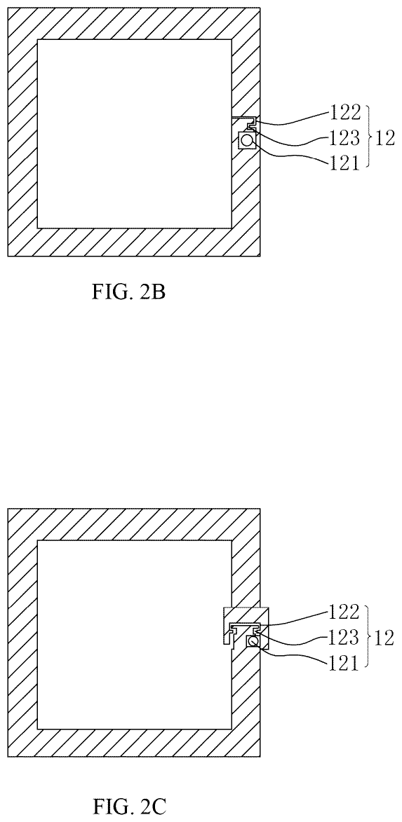

FIGS. 2A to 2C illustrate the structure and number of the gas-exhaust sub-channels 123 in the second channel section 122. Those skilled in the art can know that the number and shape of the gas-exhaust sub-channels 123 can be determined according to actual needs, and are not limited herein.

In a feasible implementation, the first channel section and the second channel section perpendicularly intersect with each other. When the deposition material of the closure portion 13 flows to the turning corner, the deposition material contacts a wall of the turning corner. Since two adjacent walls are perpendicular to each other, the walls do not provide the deposition material with friction to continue flowing. The deposition material is easy to accumulate at the turning corner, and thus having a better hindering effect on the deposition material.

In an embodiment, as shown in FIG. 1 and FIGS. 2A to 2C, two cavities 14 spaced from each other are formed in the closed space, that is, a first cavity 141 and a second cavity 142. The first cavity 141 is a high-pressure cavity, and the second cavity 142 is a low-pressure cavity. The pressure in the first cavity 141 is greater than the pressure in the second cavity 142. The gas-exhaust channel 12 is formed in the second base 9 and the bonding structure 8. In a feasible implementation, a main part of the first channel section 121 is located in the second base 9, and the second channel section 122 is located in the bonding structure 8. A position where the first channel section 121 is connected to the second channel section 122 is located at the bonding structure 8. An end of the gas-exhaust channel 12 forms a first aperture at an outer wall of the second base 9, and the first aperture is formed at an end of the first channel section 121. Another end of the gas-exhaust channel 12 forms a second aperture at an inner wall of the bonding structure 8, and the second aperture is formed at an end of the second channel section 122. The gas-exhaust channel 12 is connected to the first cavity 141 via the second aperture.

Further, the first channel section 121 extends along a height direction of the inertia measurement unit, and the second channel section 122 extends along a horizontal direction. The first channel section 121 and the second channel section 122 perpendicularly intersect with each other. The first aperture is formed at a top surface of the second base 9. In this way, the deposition and formation of the closure portion 13 can be facilitated. The closure portion 13 covers the top surface of the second base 9 to close the first aperture. The closure portion 13 is a film structure formed by depositing a dielectric or electric-conductive material. After the cavity pressure of the first cavity 141 reaches a preset requirement, a layer of dielectric or electric-conductive material is deposited at the top surface of the second base 9, so that each cavity 14 is restored to be a closed cavity, thereby improving the working stability.

In a possible implementation, as shown in FIG. 1, the support portion 7 includes a plurality of support blocks 71. A bottom of the support block 71 is connected to the first electric-conductive layer 3, and a top of the support block 71 is connected to the second electric-conductive layer 5. A cavity is formed between adjacent support blocks 71. The second electric-conductive layer 5 located above the cavity is a movable mass. When the movable mass is displaced, a distance between the moveable mass and the first electric-conductive layer 3 is changed, so that a capacitance signal in a corresponding direction can be detected to measure the inertia.

In an embodiment, a plurality of connection blocks 10 are formed by protruding from a bottom surface of the second base 9. The connection block 10 is connected to the bonding structure 8. A groove 11 is formed between adjacent connection blocks 10, and each cavity 14 corresponds to a respective groove 11, to provide space for displacement of the second electric-conductive layer 5.

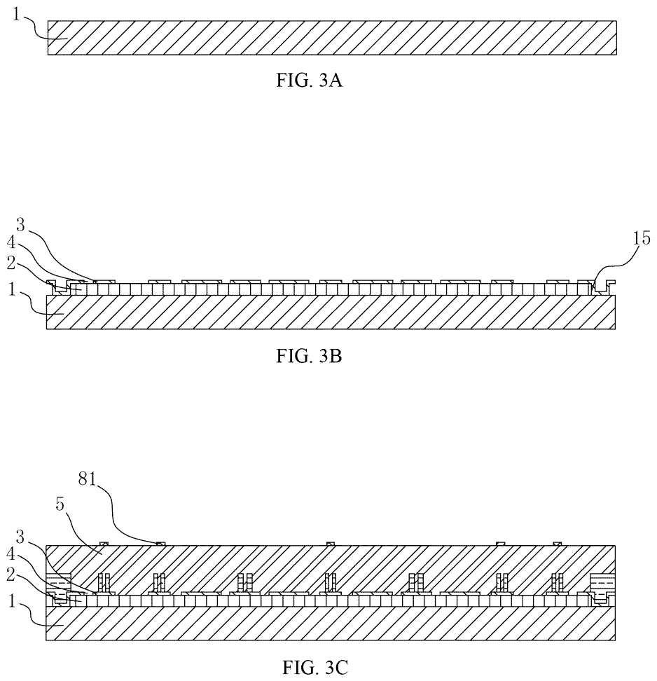

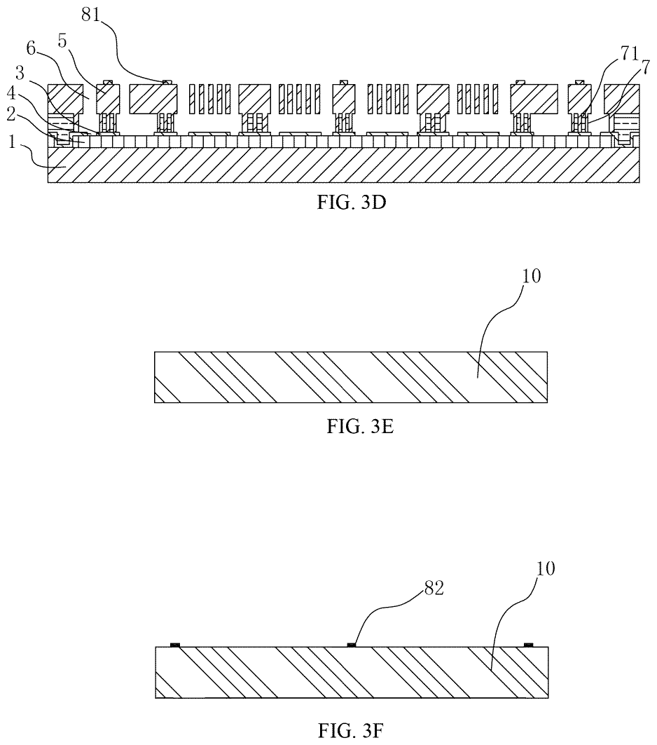

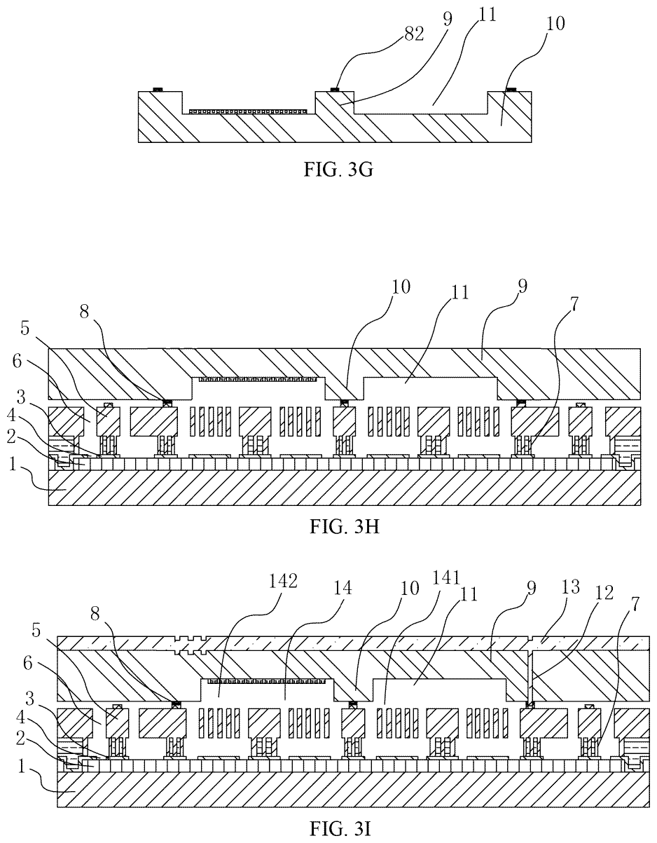

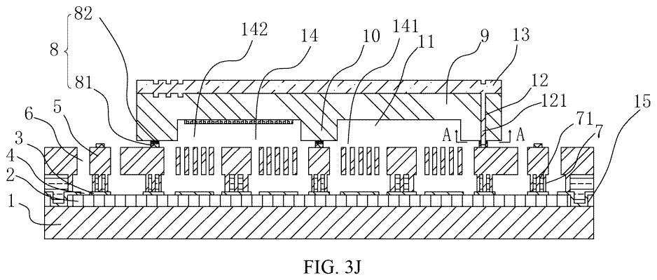

Based on the above-described embodiments, with reference to FIGS. 3A-3C, some embodiments of the present disclosure further provide a method for forming an inertial sensor. The method includes the following steps.

At S101, with reference to FIG. 3A, a first base 1 is formed.

At S102, with reference to FIG. 3B, a dielectric layer 2 and a first electric-conductive layer 3 are formed on the first base 1, the dielectric layer 2 includes a notch 15, and a first opening 4 is formed in the first electric-conductive layer 3.

In this step, the dielectric layer 2 is formed by deposition on the first base 1, the dielectric layer 2 includes a notch 15, and the first electric-conductive layer 3 is formed on the dielectric layer 2 by deposition. A resist layer is deposited on a surface of the first electric-conductive layer 3, and the resist layer is patterned using a photolithography process to form a mask. The first electric-conductive layer 3 is etched through the mask to form the first opening 4 penetrating through the first electric-conductive layer 3.

At S103, with reference to FIG. 3C, a second electric-conductive layer 5 is formed on the first electric-conductive layer 3, and a first bonding layer 81 formed on the second electric-conductive layer 5.

In this step, the first bonding layer 81 is formed on the surface of the second electric-conductive layer 5 by, for example, deposition and etching.

At S104, with reference to FIG. 3D, a second opening 6 and a support portion 7 are formed at the second electric-conductive layer 5.

In this step, a resist layer is formed on the surface of the second electric-conductive layer 5, and the resist layer is patterned using a photolithography process to form a mask. The second electric-conductive layer 5 is etched through the mask to form the second opening 6 penetrating through the second electric-conductive layer 5.

At S105, with reference to FIG. 3E, a second base 9 is formed.

At S106, with reference to FIG. 3F, a second bonding layer 82 is formed on the second base 9.

In this step, the second bonding layer 82 is formed on the surface of the second base 9 by, for example, deposition and etching.

At S107, with reference to FIG. 3G, a groove11 is formed at second base 9.

In this step, a resist layer is formed on the bottom surface of the second base 9, and the resist layer is patterned using a photolithography process to form a mask. The second base 9 is etched through the mask to form the groove 11.

At S108, with reference to FIG. 3H, the first bonding layer 81 and the second bonding layer 82 are bonded at a high temperature to form a bonding structure 8, and a closed space is formed between the second base 9 and the first base 1. The closed space includes a plurality of cavities 14 spaced from one another, and each cavity 14 corresponds to a respective groove 11.

At S109, with reference to FIG. 3I, a gas-exhaust channel 12 is formed in the second base 9 and the bonding structure 8 to release the air in at least one cavity 14. In an embodiment, the closed space includes a first cavity 141 and a second cavity 142, and the gas-exhaust channel 12 is used to release the air in the first cavity 141.

At S110, with further reference to FIG. 3I, a closure portion 13 is deposited on the second base 9 to close the gas-exhaust channel 12.

In this step, the material of the closure portion 13 may be a dielectric or electric-conductive material, so that each cavity 14 is restored to be a closed cavity, thereby improving the working stability.

At S111, with reference to FIG. 3J, the inertia measurement unit is formed.

The structures, features and effects of the present disclosure have been described in detail based on the embodiments accompanying with the drawings. The above descriptions are only preferred embodiments of the present disclosure, and a scope of the present disclosure is not limited by embodiments accompanying with the drawings. Any changes made in accordance with a concept of the present disclosure, or modifications to equivalent embodiments with equivalent changes, which do not exceed a spirit covered by the description and drawings, shall be considered as falling into a scope of the present disclosure.

What is claimed is:

1. An inertia measurement unit, comprising:
a first base;
a dielectric layer stacked on the first base and comprising a notch;
a first electric-conductive layer stacked on the dielectric layer, wherein first openings are formed in the first electric-conductive layer;
a second electric-conductive layer supported on the first electric-conductive layer by means of a support portion, wherein second openings are formed in the second electric-conductive layer;
a second base, wherein the second base covers the second electric-conductive layer by means of a bonding structure, a closed space is formed between the second base and the first base, the closed space comprises a plurality of cavities spaced from one another, and the plurality of cavities have different cavity pressures;
a gas-exhaust channel connected to one of the plurality of cavities and configured to connect the one of the plurality of cavities with an outer environment; and
a closure portion configured to close the gas-exhaust channel.

2. The inertia measurement unit as described in claim 1, wherein the gas-exhaust channel comprises a first channel section and a second channel section, an end of the first channel section is connected to the outer environment, another end of the first channel section is connected to an end of the second channel section, and another end of the second channel section is connected to the cavity connected to the gas-exhaust channel.

3. The inertia measurement unit as described in claim 2, wherein the second channel section comprises a plurality of gas-exhaust sub-channels successively connected to one another.

4. The inertia measurement unit as described in claim 2, wherein the first channel section and the second channel section perpendicularly intersect with each other.

5. The inertia measurement unit as described in claim 1, wherein the number of the plurality of cavities is set to be n, where n≥2; and the number of cavities connected to the gas-exhaust channel is set to be (n−1) or n.

6. The inertia measurement unit as described in claim 1, wherein the sealed space comprises a first cavity and a second cavity spaced from each other, a cavity pressure in the first cavity is greater than a cavity pressure in the second cavity, the gas-exhaust channel is formed in the second base and the bonding structure, an end of the gas-exhaust channel forms a first aperture at an outer wall of the second base, another end of the gas-exhaust channel forms a second aperture at an inner wall of the bonding structure, and the gas-exhaust channel is connected to the first cavity via the second aperture.

7. The inertia measurement unit as described in claim 6, wherein the first aperture is formed at a top surface of the second base, and the closure portion covers the top surface of the second base to close the first aperture.

8. The inertia measurement unit as described in claim 1, wherein the bonding structure comprises a first bonding layer and a second bonding layer connected by bonding, the first bonding layer is stacked at a top of the second electric-conductive layer, and the second bonding layer is stacked at a bottom of the second base.

9. The inertia measurement unit as described in claim 1, wherein a plurality of connection blocks are formed by protruding from a bottom surface of the second base, the plurality of connection blocks are connected to the bonding structure, and a groove is formed between adjacent connection blocks of the plurality of connection blocks.

10. A method for forming an inertia measurement unit,
wherein the inertia measurement unit comprises:
a first base;
a dielectric layer stacked on the first base and comprising a notch;
a first electric-conductive layer stacked on the dielectric layer, wherein first openings are formed in the first electric-conductive layer;
a second electric-conductive layer supported on the first electric-conductive layer by means of a support portion, wherein second openings are formed in the second electric-conductive layer;
a second base, wherein the second base covers the second electric-conductive layer by means of a bonding structure, a closed space is formed between the second base and the first base, the closed space comprises a plurality of cavities spaced from one another, and the plurality of cavities have different cavity pressures;
a gas-exhaust channel connected to one of the plurality of cavities and configured to connect the one of the plurality of cavities with an outer environment; and
a closure portion configured to close the gas-exhaust channel, and,
wherein the method for forming the inertia measurement unit comprises:
forming the first base;
forming the dielectric layer and the first electric-conductive layer on the first base, the dielectric layer comprising the notch; and forming the first openings in the first electric-conductive layer;
forming the second electric-conductive layer on the first electric-conductive layer, and forming a first bonding layer on the second electric-conductive layer;
forming the second openings in the second electric-conductive layer, and forming the support portion at the second electric-conductive layer;
forming the second base;
forming a second bonding layer on the second base;
forming a groove at the second base;
bonding the first bonding layer and the second bonding layer together at a high temperature to form the bonding structure, and forming the closed space between the second base and the first base, the closed space comprising the plurality of cavities spaced from one another;
forming the gas-exhaust channel in the second base and the bonding structure to release air in at least one of the plurality of cavities;
forming the closure portion by depositing on the second base, to close the gas-exhaust channel; and
forming the inertia measurement unit.
